(19) United States
(12) Patent Application Publication
(10) Pub. No.: US 2016/0261261 A1
(43) Pub. Date: Sep. 8, 2016

(54) Methods and Apparatus for a Burst Mode Charge Pump Load Switch

(71) Applicant: GLF Integrated Power, Inc., Santa Clara, CA (US)

(72) Inventors: Stephen W. Bryson, Cupertino, CA (US); Ni Sun, Sunnyvale, CA (US)

(21) Appl. No.: 14/638,989

(22) Filed: Mar. 4, 2015

(51) Int. Cl. H03K 17/082; H02H 9/04

(52) U.S. Cl. CPC H03K 17/0822; H02H 9/04

(57) ABSTRACT

A fully integrated circuit configuration that can be used to control the gate voltage of a power NMOS load switch using a unique method of controlling the charge pump voltage by utilizing a feedback loop to regulate the gate voltage and turning off the charge pump periodically in order to save power. This configuration is suitable for load switch applications where the input voltage can be as low as 0.8V.

### BACKGROUND

As modern portable systems become more sophisticated and more densely packed, there has come a need for circuits and devices to operate at much lower supply voltages. Many processors and memories now operate at voltages of around 1V or lower. In order to protect these systems, the load switch has been widely adopted as a method to both protect the load as well as control the off and on characteristics of the load device.

For previous generations of systems where the supply voltages are above 2V, the predominant load switch technology has been the PMOS power transistor used as a switch, as shown in FIG. 1. With the PMOS device as the load switch, the gate is brought to the ground potential in order to turn on the PMOS load switch. For a PMOS load switch device to be fully enhanced enough to provide a low impedance path between the source and the load, the source voltage must be at least 2 times greater than the gate threshold voltage; that is to say that for a typical CMOS process the V_{T} of the PMOS load switch device is about 0.8V, thus for complete enhancement of the device the source voltage must be 1.6V above the gate voltage. One advantage that the PMOS load switch device has is that it consumes virtually no power in the ON state since the gate voltage can be held at the ground potential by a simple inverter. However, as system voltages trend below 2V, the PMOS load switch becomes less attractive due to the fact that the R_{DSON} of the PMOS device increases with lower gate to source voltages.

For systems that have supply voltages in the 1V range, the PMOS load switch is not usable and the device of choice becomes a NMOS load switch transistor device. However with the NMOS transistor as a load switch, the gate voltage must now exceed the source voltage in order for the NMOS transistor to turn on. Since the input voltage is around 1V, this means that the voltage on the gate must be at least 2*V_{T} above the voltage at the source for the NMOS transistor to be turned on and fully enhanced. In order to accomplish this task, the circuit must pump the gate voltage higher than the source voltage by means of a charge pump. This technique is widely used in the industry when controlling an NMOS load switch. However, this technique does have a significant drawback; power dissipation. Unlike the PMOS device whose gate can be controlled by a simple inverter, the NMOS device requires a charge pump and an oscillator circuit to be actively running during the time that the NMOS switch is turned on in order to maintain the gate voltage. This consumes power and takes away from the power that is available to run the system at the output of the NMOS load switch. Furthermore, the power dissipation of the charge pump system is related to the square of its supply voltage (equation 1), so that if the input voltage to the switch should be raised, so will the power dissipation.

Pavg=C_{EXT}*VDD²*Fclk (1)

In the prior art system (FIG. 2), the charge pump and the oscillator remain on during the entire time that the NMOS load switch is allowed to be on.

Other prior art techniques have been used to try to get around the power dissipation issue. One such prior art embodiment replaces the ring oscillator with a voltage controlled oscillator (VCO). In this prior art system (FIG. 3), the VCO is controlled by the gate voltage of the power switch; as the gate voltage reaches its predetermined set voltage, the VCO will reduce the frequency of the clock that is running the charge pump thereby reducing the power dissipation of the overall system. However, in this approach even though the clock frequency is reduced, it still must operate the entire time that the power switch is in the on state, thus still dissipating power.

### SUMMARY

Embodiments described include a power NMOS load switch that is controlled by a charge pump and oscillator. The control of the oscillator is determined by a comparator and a feedback network.

In a preferred embodiment, the feedback network is comprised of two capacitors. The ratio of the two capacitors determine the overall gain of the feedback system. Since the gate voltage on the power NMOS switch will be several times greater than the input voltage that is the power supply for the digital circuits, the ratio must place the feedback voltage to the comparator below the input voltage of the NMOS load switch.

### BRIEF DESCRIPTION OF THE DRAWINGS

FIG. 1 shows an embodiment of a conventional NMOS load switch application.

FIG. 2 shows a conventional PMOS load switch application.

FIG. 3 shows a conventional load switch application using a VCO with a charge pump.

FIG. 4 is an overall block diagram of the burst mode charge pump and NMOS load switch according to embodiments described herein.

FIG. 5 shows the timing chart for the burst mode operation of the burst mode charge pump and NMOS load switch illustrated in FIG. 4.

FIG. 6 shows a charge pump sub-circuit of the burst mode charge pump and NMOS load switch illustrated in FIG. 4.

FIG. 7 shows a ring oscillator sub-system of the burst mode charge pump and NMOS load switch illustrated in FIG. 4.

FIG. 8 shows a schematic of the Schmitt trigger comparator that can used to control the on and off behavior of the oscillator of the burst mode charge pump and NMOS load switch illustrated in FIG. 4.

FIG. 9 shows a schematic diagram for a low voltage analog P-channel input comparator that can be used in place of the Schmitt trigger comparator.

FIG. 10 shows a further embodiment using a filter block to control the slew rate of the NMOS load switch.

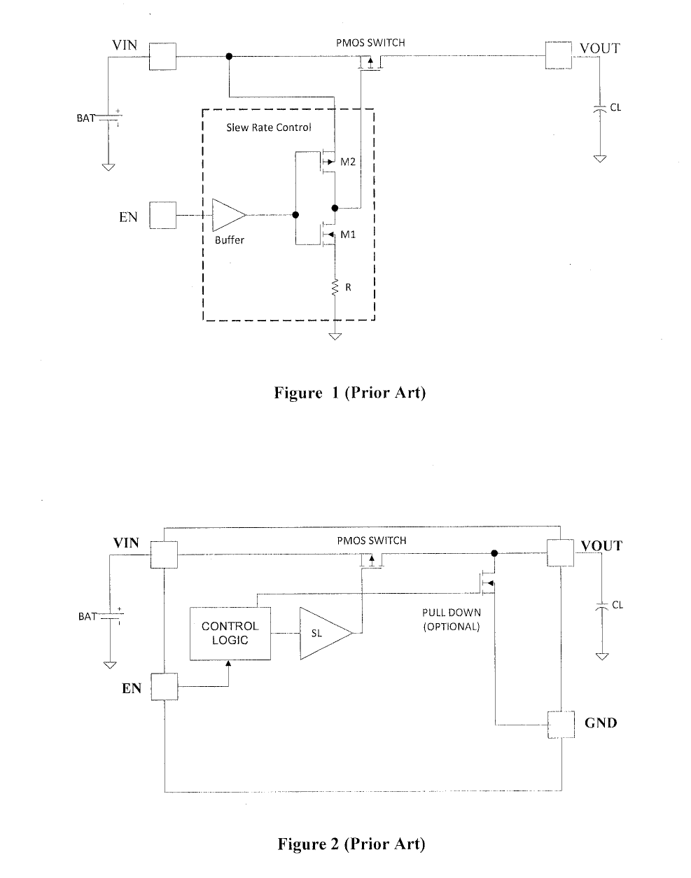

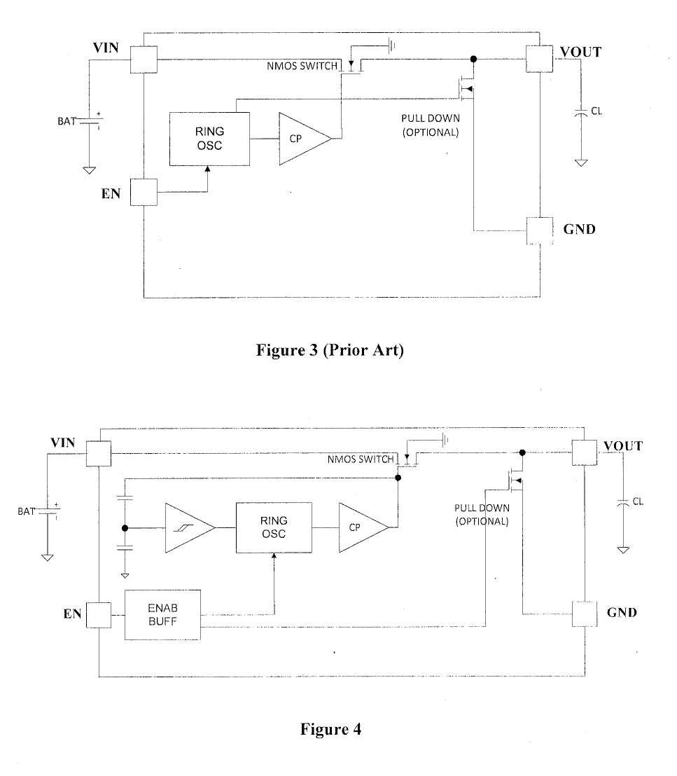

### DESCRIPTION OF THE PREFERRED EMBODIMENTS

The concept of the a burst mode charge pump as described herein introduces a feedback control loop in order to regulate the gate voltage of an NMOS load switch. By introducing the control loop, it is possible to use the charge pump and oscillator to pump up the gate voltage to a prescribed value that is set by the ratio of the feedback network and then turn the charge pump and oscillator off once the threshold voltage has been achieved thereby saving power. Specific embodiments are described below, which are not intended as limiting.

Since the gate of an NMOS load switch is primarily a capacitance, the voltage on the gate can stay stable for a long period of time and not require refreshing until the gate leakage causes the voltage level to decay to some predetermined threshold value, wherein the feedback system will respond and once again turn on the charge pump and oscillator to recharge the NMOS gate voltage.

One embodiment includes a power NMOS load switch that is controlled by a charge pump and oscillator. The control of the oscillator is determined by a comparator and a feedback network that is comprised of two capacitors. The ratio of the two capacitors determine the overall gain of the feedback system. Since the gate voltage on the power NMOS switch will be several times greater than the input voltage that is the power supply for the digital circuits, the ratio must place the feedback voltage to the comparator below the input voltage of the switch.

The capacitive divider is used to ratio the feedback voltage into the comparator because a resistive divider network to ground would produce a constant current flow from the charge pump output to ground necessitating that the charge pump be operated continuously to supply that load current; exactly the opposite of what is trying to be achieved. The capacitive divider will draw no current and will divide down the voltage appropriately. The burst mode of operation regulates the on time of the ring oscillator and charge pump in order to achieve lower overall power dissipation.

Referring to the figures and drawings in detail, FIG. 4 shows a preferred embodiment including a power NMOS load switch connected between the VIN pin and the VOUT. Being an NMOS switch, it will have the bulk node of the device connected to substrate ground. The gate of the NMOS power load switch is then connect to the output of a low voltage charge pump CP, with an input to the charge pump being the voltage c,

An example of a charge pump CP that can be used with the embodiment of FIG. 4 is shown in FIG. 6, The configuration of the charge pump is that of a CTS (charge transfer switch) which is well known in the industry. The charge pump functions in the following manner. When CLK is high and CLKB is low, the voltage on C1 goes from V1 to V1+ΔV=V2. Then on the next clock cycle the voltage on C2 goes to V2+ΔV=V3, and so forth until the VOUT level is reached.

For this NMOS load switch to work properly, the charge needs to be transferred forward during each cycle which means that switch MS2 must be turned on by the voltage on C3. The gate to source voltage of MS2 is 2 ΔV which must be larger than the V_{T} of MS2. That is:

2ΔV>V_{T} (2)

The gain of the CTS charge pump voltage stage gain can be given by the equation:

G_{V}=G_{V2}=V2−V1=ΔV (3)

Although the CTS charge pump is used as part of the current embodiment, other charge pump types of circuits could be used with equal results, as noted above. The uniqueness of the embodiments described herein do not rely on a specific type of charge pump circuit to achieve the end result.

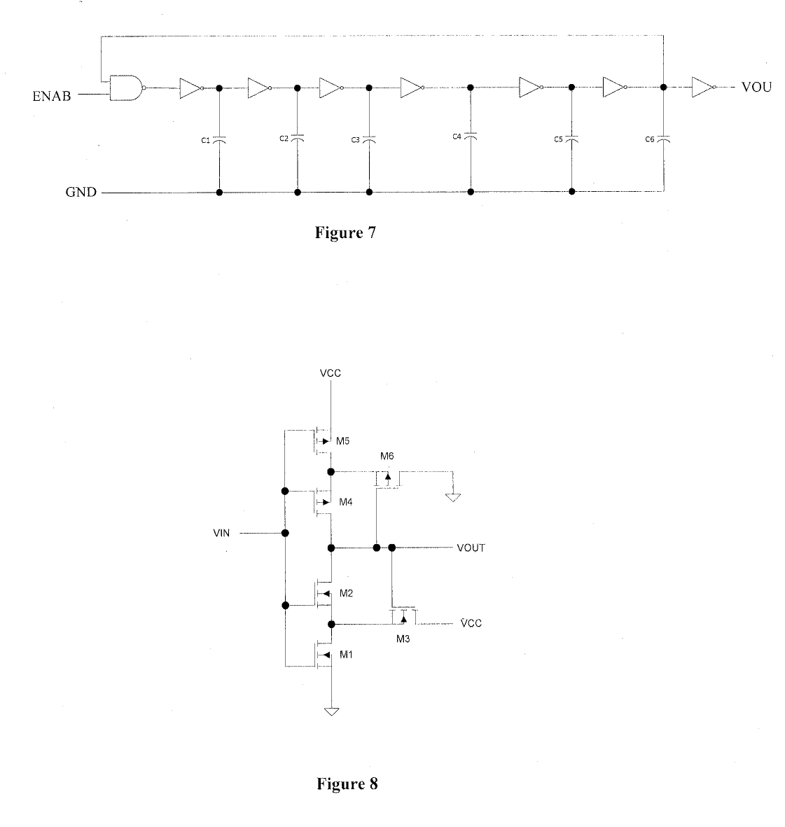

Accompanying the charge pump CP is a ring oscillator circuit, an example of which is shown in FIG. 7. This type of oscillator circuit is chosen for this type of application because of the fact that it can work down in the sub-1V region. However, the down side of using the ring oscillator is the fact that the power dissipation increases with the frequency of operation and with the square of the supply voltage as shown in equation 1. The ring oscillator is well known in the industry and is described in detail in many text books on digital design.

The final block in the control loop is the comparator, and various types of comparators that can be used are described further below. The comparator, generally, is used to provide the set points for the switching on and off of the ring oscillator by measuring the divided down gate voltage of the NMOS load switch.

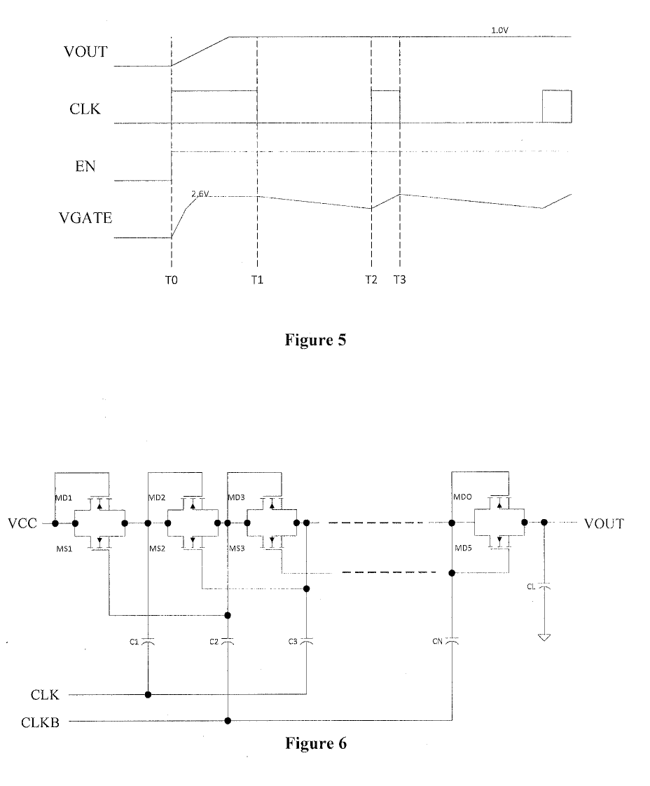

With the control loop in mind, reference is made to the system operation shown in FIG. 5. The operation starts at time T0 when the EN input pin is brought to a logic level HIGH. That action turns on the ring oscillator and the charge pump pumping up the gate voltage, VGATE, of the NMOS switch until VOUT is equal to the voltage on the VIN pin. Once the enhanced gate voltage is achieved at time T1, the ring oscillator and charge pump are turned off by the comparator in the feedback loop. Then the voltage on VGATE will be allowed to droop down until time T2 when the comparator will once again turn on the charge pump and allow the voltage at VGATE to be pumped back up until time T3, when the comparator will once again turn off the charge pump. Using this technique, the only time that the system is dissipating power is the time where the oscillator is running and the charge pump is pumping up the voltage at VGATE. The other times, the power dissipation is near zero.

As was mentioned above, since the gate voltage on the power NMOS switch will be several times greater than the input voltage that is the power supply for the digital circuits, the ratio must place the feedback voltage to the comparator below the input voltage of the switch. The Schmitt trigger circuit is one preferred type of comparator that can be used and which has a built in hysteresis that allows for such ratio to be easily satisfied. The rising level threshold on the input of the Schmitt trigger device can be set by adjusting the W/L ratios of transistors M1 and M3 in FIG. 8, while the falling threshold can be adjusted by the W/L ratios of transistors MS and M6. The Schmitt trigger comparator is the preferred choice for a comparator at low voltages; however, for higher input voltages, the use of a traditional analog comparator provides more flexibility in design and can improve the accuracy and the gate voltage control over the Schmitt trigger comparator.

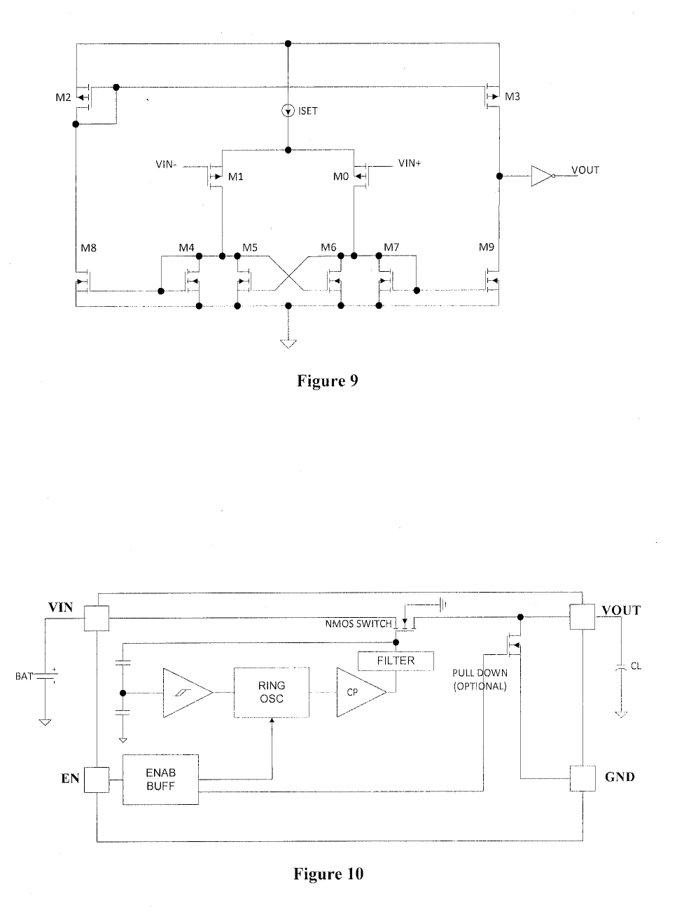

While the Schmitt trigger comparator is suitable for this application since it is essentially a pseudo-digital circuit and can operate at very low supply voltages, a low voltage analog comparator design (FIG. 9) can also be used along with a suitable reference voltage.

FIG. 10 shows a further embodiment where the control loop includes a filter block which is connected in between the output of the charge pump and the gate voltage of the NMOS load switch. The filter is used to control the slew rate of the gate voltage during the turn on time at start up. The technique is used to provide a controlled turn on in order to limit the inrush current from VIN to the load capacitance at VOUT.

Although described herein with reference to the preferred embodiment, one skilled in the art will readily appreciate that other applications may be substituted for those set forth herein without departing from the intended spirit and scope.

What is claimed is:

1. A switching circuit connectable between an input source voltage and an output load for controlling an inrush current to the output load upon turn-on, the switching circuit further operating using a VIN voltage, the switching circuit including:
an integrated circuit, the integrated circuit including:
a power NMOS load switch including a load switch gate, a load switch source and a load switch drain, the inrush current to the output load passing from the load switch source to the load switch drain and being controlled by a load switch control voltage on the load switch gate; and
a control circuit connected to the load switch gate of the power NMOS load switch that provides the ability to pump the gate voltage of the NMOS switch above the VIN voltage, the control circuit including:
a charging circuit that turns on until the gate voltage of the NMOS load switch rises about the VIN when turned on; and
a feedback circuit coupled between the power NMOS load switch and the charging circuit, which turns on the charging circuit when the gate voltage of the NMOS load switch decreases below a predetermined threshold.

2. The switching circuit according to claim 2, wherein the charging circuit includes an oscillator that is used to provide clocking inputs to a charge pump and is controllable by both an EN input pin as well as a control loop of the feedback circuit.

3. The switching circuit according to claim 2 wherein the oscillator is a ring oscillator.

4. The switching circuit according to claim 2 wherein the charge pump is a charge transfer switch.

5. The switching circuit according to claim 2, wherein the feedback circuit further includes a comparator circuit that provides the predetermined threshold and hysteresis of the control loop to control the ring oscillator.

6. The switching circuit according to claim 5, wherein the feedback circuit includes a capacitive divider circuit that is used to set a control loop gain between an input of the comparator circuit and the gate voltage of the NMOS load switch.

7. The switching circuit according to claim 6 wherein the capacitor divider circuit includes two capacitors that determine the control loop gain.

8. The switching circuit according to claim 5/6/7 wherein the comparator is a Schmitt trigger comparator.

9. The switching circuit according to claim 5/6/7 wherein the comparator is a low voltage analog comparator.

10. The switching circuit according to claims 1-9, further including a filter for controlling a slew rate of the gate voltage of the NMOS load switch.
